(19) United States
(12) Patent Application Publication
(10) Pub. No.: US 2006/0270215 A1
(43) Pub. Date: Nov. 30, 2006

(54) Semiconductor device and method of manufacturing the same

(75) Inventors: Kong-Soo Lee, Hwaseong-si (KR); Chang-Hoon Lee, Seoul (KR); Young-Sub You, Pyeongtaek-si (KR); Jung-Hwan Oh, Yongin-si (KR); Sang-Jin Park, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/437,625

(22) Filed: May 22, 2006

(30) Foreign Application Priority Data
May 30, 2005 (KR) 2005-0045393

(51) Int. Cl. H01L 21/44; H01L 21/4763; H01L 23/48

(52) U.S. Cl. 438/637; 438/597; 257/774

(57) ABSTRACT

A semiconductor device and a method of manufacturing the semiconductor device may include a layered structure and a plug. The layered structure may have a lower insulation layer pattern, a single crystalline silicon pattern, and an upper insulation layer pattern provided on a substrate. A contact hole may be provided in the layered structure. The contact hole may expose the single crystalline silicon pattern and the substrate. The plug may include silicon germanium. The plug may be provided in the contact hole and may be electrically connected to the substrate and the single crystalline silicon pattern.

### PRIORITY STATEMENT

This application claims priority under 35 USC §119 from Korean Patent Application No. 2005-45393 filed on May 30, 2005, the contents of which are herein incorporated by reference in their entirety.

### BACKGROUND

1. Field of the Invention

Example embodiments of the present invention may relate to a semiconductor device and a method of manufacturing the semiconductor device. More particularly, example embodiments of the present invention may relate to a stacked semiconductor device having a plug connected to a single crystalline silicon pattern and a method of manufacturing a stacked semiconductor device having the plug connected to the single crystalline silicon pattern.

2. Description of the Related Art

A pattern width in a unit cell of a semiconductor device may be reduced. However, the reduced pattern width of the semiconductor device may cause various problems, such as (for example) an increase of an electrical resistance of the pattern and/or significant variation of operation characteristics of the semiconductor device. For the above reasons, there may be limits as to how much the pattern width may be reduced.

To increase the integration degree of the semiconductor device, a single crystalline silicon pattern may be formed on a semiconductor substrate and a plurality of unit elements of the semiconductor device, such as a metal-oxide semiconductor (MOS) transistor, may be stacked on the single crystalline silicon pattern.

The above stacked structure on the single crystalline silicon pattern may be utilized for a static random access memory (SRAM) device, for example. A complementary MOS (CMOS) SRAM device may include six transistors in a unit cell, so the unit cell of the full CMOS SRAM device may occupy a larger area of the substrate for the transistors than any other memory device. Hereinafter, the SRAM device including the above stacked structure on the single crystalline silicon pattern may be referred to as a stacked SRAM device.

To form a conventional stacked SRAM device, a single crystalline silicon pattern may be vertically stacked on a substrate as a channel layer for the stacked SRAM device. Each of the unit transistors may be provided on the single crystalline silicon pattern. Each of the unit transistors on the single crystalline silicon pattern may be electrically connected to each other by a contact plug. For example, gate electrodes of the unit transistors and/or source/drain regions of the unit transistors may be electrically connected to each other in the conventional stacked SRAM device.

An ohmic layer may be provided on the plug so that contact portions of the plug may have desired ohmic contact properties. The ohmic layer may be fabricated from a metal silicide material. A barrier metal layer may be provided on an inner surface of a contact hole in which the plug may be provided. The barrier metal layer may be heat treated to provide the ohmic layer.

Although conventional devices and/or techniques are generally thought to provide acceptable performance, they are not without shortcomings. For example, the barrier metal layer may be difficult to provide uniformly on the inner surface of the contact hole. As a diameter of the contact hole becomes reduced and a depth of the contact hole becomes increased, the barrier metal layer may have a non-uniform thickness and/or no barrier metal layer may be locally formed on the inner surface of the contact hole. When a non-uniform barrier metal layer is heat treated, a non-uniform metal silicide layer may be provided in the contact hole, and/or the metal silicide layer may not be provided on intended regions of the contact hole surface. Accordingly, the ohmic contact properties of the contact plug may be deteriorated due to the non-uniformity of the metal silicide layer.

Further, when the barrier metal layer is heat treated to form the metal silicide layer in the contact hole, the single crystalline silicon pattern and the barrier metal layer may react with each other, and a portion of a sidewall of the single crystalline silicon pattern may be excessively removed from the substrate. The excessive removal of the single crystalline silicon pattern may exhaust impurities doped in the source/drain regions of the unit transistors on the single crystalline silicon pattern, which may generating an operation failure of the stacked SRAM device.

Furthermore, repeated heat treatment for formation of the metal silicide layer may degrade operation characteristics of the unit transistors on the substrate and/or the single crystalline silicon pattern due to the application of heat of a high temperature.

### SUMMARY

According to an example, non-limiting embodiment, a semiconductor device may include a substrate. A layered structure may be provided on the substrate. The layered structure may include a lower insulation layer pattern provided on the substrate. A single crystalline silicon pattern may be provided on the lower insulation layer pattern. An upper insulation layer pattern may be provided on the single crystalline silicon pattern. A contact hole may be provided in the layered structure. The single crystalline silicon pattern and the substrate may be exposed in the contact hole. A plug, which may include crystalline silicon germanium, may be positioned in the contact hole. The plug may be electrically connected to the single crystalline silicon pattern and the substrate.

According to another example non-limiting embodiment, a method of manufacturing a semiconductor device may involve providing a layered structure on a substrate. The layered structure may include a lower insulation layer pattern provided on the substrate, a single crystalline silicon pattern provided on the lower insulation layer pattern, and an upper insulation layer pattern provided on the single crystalline silicon pattern. A contact hole may be provided through the layered structure by etching the upper insulation layer pattern, the single crystalline silicon pattern, and the lower insulation layer pattern to expose the single crystalline silicon pattern and the substrate. A crystalline silicon germanium layer may be provided on the layered structure to fill the contact hole. A plug may be provided in the contact hole by planarizing the silicon germanium layer until a top surface of the layered structure is exposed. The plug may be electrically connected to the single crystalline silicon pattern and the substrate.

According to another example, non-limiting embodiment, a semiconductor device may include a first transistor of a first conductive type provided on a substrate. The first transistor may include a first impurity region and a first gate electrode. A lower insulation layer pattern may be provided on the substrate. The lower insulation layer pattern may have a first opening through which the first impurity region and the first gate electrode may be exposed. A first single crystalline silicon pattern may be provided on the lower insulation layer pattern. A second transistor of a second conductive type may be provided on the first single crystalline silicon pattern. The second transistor may include a second impurity region and a second gate electrode. An insulating interlayer pattern may be provided on the lower insulation layer pattern. The insulating interlayer pattern may have a second opening through which the second impurity region and the second gate electrode may be exposed. The second opening may be connected to the first opening. A second single crystalline silicon pattern may be provided on the insulating interlayer pattern. A third transistor of the first conductive type may be provided on the second single crystalline silicon pattern. The third transistor may include a third impurity region and a third gate electrode. An upper insulation layer pattern may be provided on the insulating interlayer pattern. The upper insulation layer pattern may have a third opening through which the third impurity region may be exposed. The third opening may be connected to the second opening. A plug may fill the first, the second and the third openings. The plug may include crystalline silicon germanium.

According to another example, non-limiting embodiment, a method of manufacturing a semiconductor device may involve providing a first transistor of a first conductive type on a substrate. The first transistor may include a first impurity region and a first gate electrode. A lower insulation layer pattern may be provided on the substrate to cover the first transistor. A first single crystalline silicon pattern may be provided on the lower insulation layer pattern. A second transistor of a second conductive type may be provided on the first single crystalline silicon pattern. The second transistor may include a second impurity region and a second gate electrode. An insulating interlayer pattern may be provided on the first single crystalline silicon layer to cover the second transistor. A second single crystalline silicon pattern may be provided on the insulating interlayer pattern. A third transistor of the first conductive type may be provided on the second single crystalline silicon pattern. The third transistor may include a third impurity region and a third gate electrode. An upper insulation layer pattern may be provided on the insulating interlayer pattern to cover the third transistor. A contact hole may be provided by etching the upper insulation layer pattern, the insulating interlayer pattern, and the lower insulation layer pattern to expose the first, the second and the third impurity regions and the first and the second gate electrodes. A crystalline silicon germanium layer may be provided on the upper insulation layer pattern to fill the contact hole. A plug may be provided in the contact hole by planarizing the silicon germanium layer until a top surface of the upper insulation layer pattern is exposed.

According to another example, non-limiting embodiment, a semiconductor device may include a substrate. A lower insulation layer pattern may be provided on the substrate. A single crystalline silicon pattern may be provided on the lower insulation layer pattern. An upper insulation layer pattern may be provided on the single crystalline silicon pattern. A plug, which may include crystalline silicon germanium, may be extended through the lower insulation layer pattern, the single crystalline silicon pattern and the upper insulation layer pattern. The plug may be electrically connected to the single crystalline silicon pattern and the substrate.

### BRIEF DESCRIPTION OF THE DRAWINGS

Example, non-limiting embodiments of the present invention will become apparent by reference to the following description when considered in conjunction with the accompanying drawings.

FIG. 1 is a cross-sectional view of a semiconductor device in accordance with an example, non-limiting embodiment of the present invention.

FIGS. 2 to 5 are cross-sectional views of a method that may be implemented to manufacture the semiconductor device shown in FIG; 1, in accordance with an example, non-limiting embodiment of the present invention.

FIG. 6 is a cross-sectional view of a unit cell of a SRAM device that may have a triple-stacked structure in accordance with an example, non-limiting embodiment of the present invention.

FIGS. 7 to 10 are cross-sectional views of a method that may be implemented to manufacture the semiconductor device shown in FIG. 6, in accordance with an example, non-limiting embodiment of the present invention.

### DESCRIPTION OF EXAMPLE, NON-LIMITING EMBODIMENTS

Example, non-limiting embodiments of the present invention are described with reference to the accompanying drawings. The present invention may, however, be embodied in many different forms and should not be construed as limited to the example embodiments set forth herein. Rather, the example embodiments are provided so that this disclosure will be thorough and complete, and will fully convey the scope of the present invention to those skilled in the art. In the drawings, the sizes and relative sizes of layers and regions may be exaggerated for clarity. The drawings are not to scale. Like reference numerals refer to like elements throughout.

It will be understood that when an element or layer is referred to as being “on”, “connected to” and/or “coupled to” another element or layer, it can be directly on, connected and/or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” includes any and all combinations of one or more of the associated listed items.

Although the terms first, second, third etc. may be used herein to describe various elements, components, regions, layers and/or sections, these elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like, may be used to describe one element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular terms “a”, “an” and “the” are intended to include the plural forms as well, unless the context clearly indicates otherwise. It will be understood that the terms “comprises” and/or “comprising,” when used in this specification, specify the presence of stated features, integers, steps, operations, elements, and/or components, but do not preclude the presence and/or addition of one or more other features, integers, steps, operations, elements, components, and/or groups thereof.

The following description refers to cross-section illustrations, which may be schematic illustrations of example embodiments (and intermediate structures). As such, variations from the shapes of the illustrations as a result, for example, of manufacturing techniques and/or tolerances, may be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded and/or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes are not intended to illustrate the actual shape of a region of a device and are not intended to limit the scope of the present invention.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

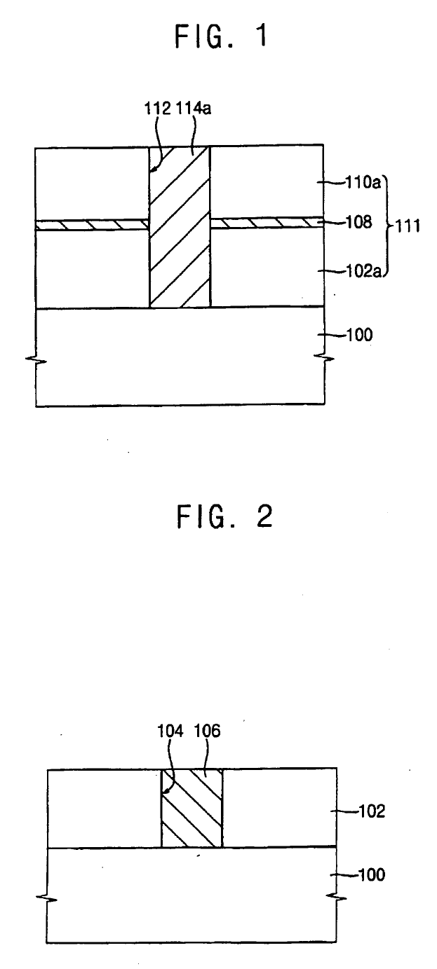

FIG. 1 is a cross-sectional view of a semiconductor device in accordance with an example, non-limiting embodiment of the present invention. Here, the semiconductor device may have a stacked structure in which a plurality of semiconductor structures may be provided on a substrate.

Referring to FIG. 1, the semiconductor device may include a layered structure 111 provided on a substrate 100. A plug 114a may extend through the layered structure 111.

The substrate 100 may include a single crystalline silicon substrate and/or a silicon-on-insulator (SOI) substrate, for example. The layered structure 11 may include a lower insulation layer pattern 102a provided on the substrate 100, a single crystalline silicon pattern 108 provided on the lower insulation layer pattern 102a, and an upper insulation layer pattern 110a provided on the single crystalline silicon pattern 108.

By way of example only, the insulation layers 102a and 110a may include a silicon oxide such as high-density plasma (HDP) oxide and/or borophosphor silicate glass (BPSG), respectively.

The layered structure 111 may include an opening 112 through which the substrate 100 may be partially exposed. The opening 112 may be provided through the lower insulation layer pattern 102a, the single crystalline silicon pattern 108, and the upper insulation layer pattern 110a. A portion of the single crystalline silicon pattern 108 may be exposed by the opening 112. The opening 112 may include a sidewall composed of the exposed portion of the single crystalline silicon pattern 108 and portions of the upper and the lower insulation layer patterns 110a and 102a.

The plug 114a may be provided in the opening 112. The plug 114a may contact with the exposed portion of the single crystalline silicon pattern 108. In addition, the plug 114a may contact with the exposed portion of the substrate 100. Thus, the substrate 100 may be electrically connected to the single crystalline silicon pattern 108 through the plug 114a.

By way of example only, the plug 114a may include crystalline silicon germanium. Alternatively, the plug 114a may include silicon germanium doped with impurities in Group III and/or Group V of the periodic table, for example. By way of example only, the impurities may include an element in Group III such as boron (B) and/or an element in Group V such as phosphor (P) and/or arsenic (As).

The plug 114a including silicon germanium may be fabricated via a chemical vapor deposition (CVD) process at a temperature of about 400 to about 550° C., for example. Alternatively, the plug 114a including silicon germanium may be fabricated via an epitaxial growth process.

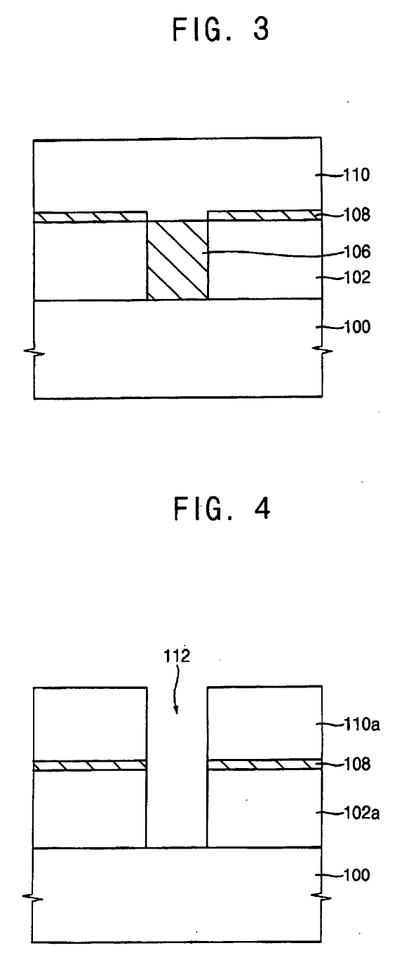

FIGS. 2 to 5 are cross-sectional views of a method that may be implemented to manufacture the semiconductor device shown in FIG. 1.

Referring to FIG. 2, a lower insulation layer 102 may be provided on a substrate 100. The substrate 100 may be fabricated from single crystalline silicon. Alternatively, the substrate 100 may be formed using a silicon-on-insulator (SOI) substrate.

The lower insulation layer 102 may be provided on the substrate 100 using a silicon oxide such as high-density plasma (HDP) oxide and/or borophosphor silicate glass (BPSG), for example. Before providing the lower insulation layer 102 on the substrate 100, a semiconductor element such as a transistor (for example) may be provided on the substrate 100.

The lower insulation layer 102 may be etched to thereby provide a first opening 104 through which a surface of the substrate 100 may be exposed. A wet surface treatment may be performed on the substrate 100 including the first opening 104 using an aqueous hydrogen fluoride (HF) solution (for example) to remove an oxide layer from the substrate 100.

An epitaxial layer (not shown) may be grown from the exposed surface of the substrate 100 to a sufficient thickness to fill the first opening 104 by an epitaxial growth process. When the epitaxial growth process is performed at a temperature under about 750° C., the growth rate of the epitaxial layer may be negligible, thereby reducing productivity, while at temperatures over about 1250° C., the growth rate of the epitaxial layer may be so rapid that the final thickness may be difficult to control accurately. Thus, the epitaxial growth process may be performed at a temperature of about 750 to about 1250° C. The epitaxial growth process may be performed at a temperature of about 800 to about 900° C. A source gas for the epitaxial growth process may include silicon, for example. The silicon source gas for the epitaxial growth process may include, for example, silicon tetrachloride (SiCl₄) gas, silane (SiH₄) gas, dichlorosilane (SiH₂Cl₂) gas, trichlorosilane (SiHCl₃) gas, etc. These materials may be used alone or in a mixture thereof

The epitaxial layer may be polished and removed until a top surface of the lower insulation layer 102 may be exposed. In this way, the epitaxial layer may remain in the first opening 104 to thereby form an epitaxial pattern 106. A top surface of the epitaxial pattern 106 may be coplanar with the top surface of the lower insulation layer 102.

Referring to FIG. 3, an amorphous silicon layer (not shown) may be provided on the lower insulation layer 102 and the epitaxial pattern 106. The amorphous silicon layer may be provided via a CVD process, for example.

The amorphous silicon layer may be heat treated to change the amorphous silicon layer into a single crystalline silicon layer (not shown). For example, a phase transformation of the amorphous silicon layer may occur by the heat treatment, and silicon that may be included in the epitaxial pattern 106 may act as a seed to change a crystalline structure of the amorphous silicon layer into a single crystalline structure.

The single crystalline silicon layer may be selectively etched from the epitaxial pattern 106 to provide a single crystalline silicon layer 108 through which a top surface of the epitaxial pattern 106 may be exposed. A semiconductor element such as a transistor (for example) may be provided on the single crystalline silicon pattern 108.

An upper insulation layer 110 may be provided on the single crystalline silicon pattern 108 and the top surface of the epitaxial pattern 106. The upper insulation layer 110 may be provided by depositing silicon oxide (for example).

Referring to FIG. 4, the upper insulation layer 110 may be etched away from the epitaxial pattern 106 to provide a second opening exposing the top surface of the epitaxial pattern 106. The epitaxial pattern 106 may be etched away from the substrate 100 to provide a third opening exposing the surface of the substrate 100. The second and the third openings may compose a contact hole 112 exposing a portion of the single crystalline silicon pattern 108 and portions of the upper and the lower insulation layer patterns 110a and 102a. In this way, a contact hole 112 may be provided through the upper insulation layer pattern 110a, the single crystalline silicon pattern 108, and the lower insulation layer pattern 102a.

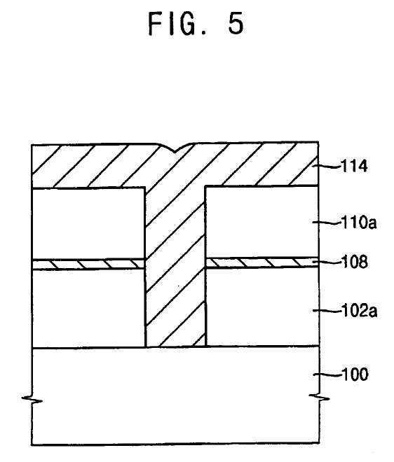

Referring to FIG. 5, a silicon germanium layer 114 may be provided on the layered structure 111 to a sufficient thickness to fill the contact hole 112. In an example embodiment of the present invention, the silicon germanium layer 114 may include crystalline silicon germanium. The silicon germanium layer 114 may be doped with impurities including elements in Group V and/or Group III of the periodic table in situ with the silicon germanium layer 114.

Atoms of the silicon germanium layer 114 may not diffuse into the upper and the lower insulation layer patterns 110a and 102a. Thus, a diffusion barrier layer may not be formed on an inner surface of the contact hole 112. Additionally, a crystal structure of the silicon germanium layer 114 may be substantially the same as that of the substrate 100 comprising single crystalline silicon and the single crystalline silicon pattern 108. Thus, an ohmic layer may not be formed on contact regions between the silicon germanium layer 114 and the single crystalline silicon substrate 100 or the single crystalline silicon pattern 108. Accordingly, the single crystalline silicon pattern 108 may be sufficiently prevented from being removed from the substrate 100.

The silicon germanium layer 114 may be deposited and/or grown. Impurities of the silicon germanium layer 114 may be activated at a temperature of about 400 to about 550° C., for example.

The silicon germanium layer 114 may be provided by a low pressure CVD (LPCVD) process and/or an epitaxial growth process. Such processes are well known in this art. The epitaxial growth process may consume a substantial amount time, as compared to the LPCVD process. This example embodiment may implement the LPCVD process.

An LPCVD process to provide the silicon germanium layer 114 may be as follows.

If the LPCVD process is performed at a temperature under about 400° C, a yield rate of the silicon germanium layer 114 may be negligible, thereby reducing productivity. If the LPCVD process is performed at a temperature over about 550° C., neighboring patterns and/or unit elements may be degraded. Thus, in this example, non-limiting embodiment, the silicon germanium layer 114 may be deposited at a temperature of about 400° C. to about 550° C. The silicon germanium layer 114 may be deposited at a temperature of about 450° C. to about 500° C.

The silicon germanium layer 114 may be deposited under a chamber pressure of about 0.1 to about 1.0 Torr. In an example embodiment of the present invention, the silicon germanium layer 114 may be deposited under a chamber pressure of about 0.3 to about 0.5 Torr.

In the above LPCVD process for providing the silicon germanium layer 114, silane (SiH₄) gas (for example) may be used as a silicon source gas and germane (GeH₄) gas (for example) may be used as a germanium source gas. A flow rate ratio of the germanium source gas with respect to the silicon source gas may be ranged from about 0.7 to about 1.3.

In an example embodiment of the present invention, a doping gas may be provided into a process chamber of an LPCVD system together with the silicon source gas and the germanium source gas, so that elements in the doping gas may be doped in situ into the silicon germanium layer 114 as impurities. For example, the doping gas for doping the silicon germanium layer 114 with elements in Group V of the periodic table may include phosphine (PH₃) gas and arsine (AsH₃) gas, and the doping gas for doping the silicon germanium layer 114 with elements in Group III of the periodic table may include diborane (B₂H₆) gas.

As described above, the crystalline silicon germanium layer 114 may be obtained at a temperature of about 400° C. to about 550° C. Additionally, the impurities doped into the silicon germanium layer 114 may be activated so that an additional heat treatment to the crystalline silicon germanium layer 114 may be omitted.

Then, as shown in FIG. 1, the silicon germanium layer 114 may be polished until a surface of the substrate 100 is exposed. A polishing process may include a chemical mechanical polishing (CMP) process and/or an etch-back process, for example. In this way, the silicon germanium layer 114 may remain in the contact hole 112 to provide the plug 114a.

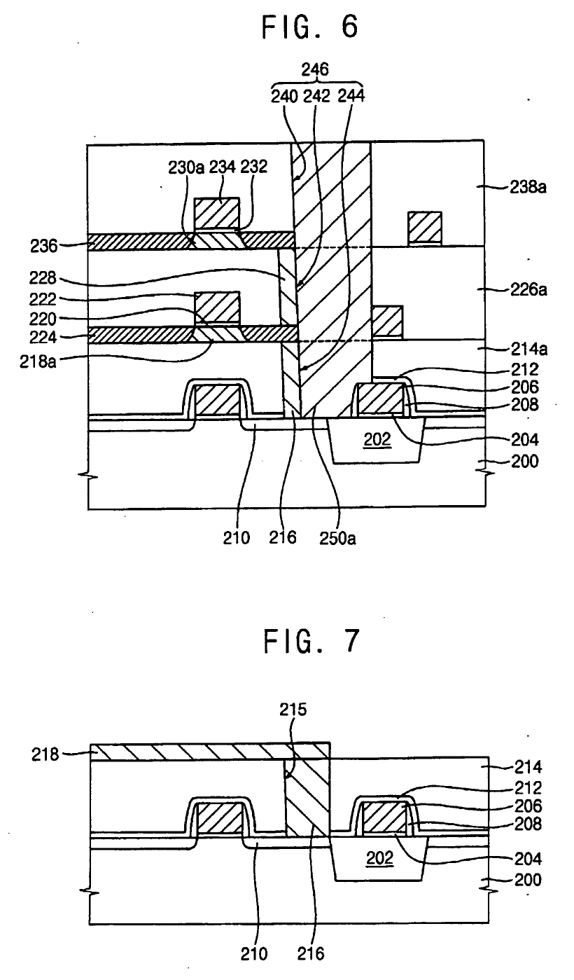

FIG. 6 is a cross-sectional view of a unit cell of a SRAM device that may implement a triple-stacked structure in accordance with an example, non-limiting embodiment of the present invention. Referring to FIG. 6, an isolation layer 202 may be provided at an upper portion of a substrate 200. The isolation layer 202 may define a lower active area and a lower field area

The substrate 200 may include single crystalline silicon, for example. Alternatively, the substrate 200 may include a silicon-on-insulator (SOI) substrate. The isolation layer 202 may be provided via a shallow trench isolation (STI) process.

N-type first transistors may be provided in the lower active area as pull-down devices. A pair of the pull-down transistors may be positioned in a unit cell of a full CMOS SRAM device.

Each of the first transistors may include a first gate insulation layer pattern 204, a first conductive layer pattern 206, and first source/drain regions 210. The first conductive layer pattern 206 may extend over the isolation layer 202 and may be connected to additional transistors provided over the first transistors by a plug 250a.

A P-well (not shown) may be provided in the substrate 200. The first source/drain regions 210 may be portions of the P-well in which N-type impurities may be doped.

A gate spacer 208 may be provided on a side face of the first gate insulation layer pattern 204 and the first conductive layer pattern 206.

A liner 212, which may include nitride, may be provided on the first conductive layer pattern 206, the gate spacer 208, and the substrate 200. The liner 212 may serve as an etch stop layer forming subsequent openings in the device.

A lower insulation layer pattern 214a may be provided on the liner 212. A first opening 244, which may expose a portion of the substrate 200 and a portion of the first conductive layer pattern 206 may be provided through the lower insulation layer pattern 214a. The first source/drain regions 210 may be exposed by the first opening 244.

The lower insulation layer pattern 214a may have a sufficient thickness to cover the first transistors on the substrate 200. The lower insulation layer pattern 214a may have a planar top surface. The lower insulation layer pattern 214a may include silicon oxide. For example, the lower insulation layer pattern 214a may include an oxide layer formed by a high-density plasma CVD (HDPCVD) process and/or borophosphosilicate glass (BPSG).

A first single crystalline silicon pattern, which may include a channel region 218a and second source/drain regions 224, may be provided on the lower insulation layer pattern 214a. The first single crystalline silicon pattern may act as a first upper active area.

A plurality of second P-type transistors may be positioned on the first single crystalline silicon pattern as pull-up transistors for the full CMOS SRAM device. A pair of the pull-up transistors may be positioned in the unit cell of the full CMOS SRAM device.

Each of the second transistors may include a second gate insulation layer pattern 220, a second conductive layer pattern 222, and the second source/drain regions 224. The channel region 218a of the second transistor may be doped with N-type impurities, and the second source/drain regions 224 of the second transistor may be doped with P-type impurities. The second source/drain regions 224 (of the first single crystalline silicon pattern) may extend to a side end portion of the channel region 218a (of the first single crystalline silicon pattern). The second conductive layer pattern 222 may extend over the lower insulation layer 214a, so that the plug 250a may contact with the second conductive layer pattern 222.

An insulating interlayer pattern 226a, which may have a second opening 242, may be provided on the lower insulation layer pattern 214a. The second opening 242 may be connected to the first opening 244. The insulating interlayer pattern 226a may include silicon oxide, for example. A portion of the first single crystalline silicon pattern (e.g., the second source/drain regions 224) and a portion of the second conductive layer pattern 222 may be exposed by the second opening 242.

A second single crystalline silicon pattern 230a, which may include a channel region 230a and third source/drain regions 236, may be provided on the insulating interlayer pattern 226a The second single crystalline silicon pattern may act as a second active area.

A plurality of third N-type transistors may be positioned on the second single crystalline silicon pattern as access transistors for the full CMOS SRAM device. A pair of the access transistors may be positioned in the unit cell of the full CMOS SRAM device.

Each of the third transistors may include a third gate insulation layer pattern 232, a third conductive layer pattern 234, and the third source/drain regions 236. The channel region 230a of the third transistor may be doped with P-type impurities, and the third source/drain regions 236 of the third transistor may be doped with N-type impurities. The third source/drain regions 236 (of the second single crystalline silicon pattern) may extend to a side end portion of the channel region 230a (of the second single crystalline silicon pattern).

An upper insulation layer pattern 238a, which may have a third opening 240 connected to the second opening 242, may be provided on the insulating interlayer pattern 226a. The upper insulation layer pattern 238a may include silicon oxide, for example. A portion of the second single crystalline silicon pattern (e.g., the third source/drain regions 236) may be exposed by the third opening 240. The first, the second and the third openings 244, 242, and 240 may be together referred to as a contact hole 246.

A first epitaxial layer pattern 216 may be provided between the substrate 200 and the second source/drain regions 224 of the first single crystalline silicon patterns. The first epitaxial layer pattern 216 may be provided by a selective epitaxial growth process. A second epitaxial layer pattern 228 may be provided between the second source/drain regions 224 of the first single crystalline silicon pattern and the third source/drain regions 236 of the second single crystalline silicon pattern. The second epitaxial layer pattern 228 may be provided by a selective epitaxial growth process. The first and the second epitaxial layer patterns 216 and 228 may be exposed by the contact hole 246.

The plug 250a may fill the contact hole 246. The plug 250a may include silicon germanium, for example. The plug 250a may be electrically connected to the first, the second and the third source/drain regions 210, 224, and 236 and the first and the second conductive layer patterns 206 and 222.

Additional two plugs (not shown) may be positioned in the unit cell of the full CMOS SRAM device, so that the source/drain regions and the gate electrode in each transistor may be connected with each other.

The plug 250a including silicon germanium may be doped with impurities in Group III and/or Group V of the periodic table.

Silicon germanium for forming the contact plug 250a may be obtained by a CVD process at a temperature of about 400 to about 550° C., for example. Alternatively, silicon germanium for forming the contact plug 250a may be obtained by an epitaxial growth process.

FIGS. 7 to 10 are cross-sectional views of a method that may be implemented to manufacture the semiconductor device shown in FIG. 6.

Referring to FIG. 7, an isolation layer 202 may be provided on a substrate 200 by an STI process, for example. The substrate 200 may be fabricated from single crystalline silicon, for example. Alternatively, the substrate 200 may include a silicon-on-insulator (SOI) substrate. The isolation layer 202 may define a lower active area and a lower field area.

A first gate insulation layer (not shown) may be provided on the substrate 200 corresponding to the first lower active area. A first conductive layer (not shown) may be provided on the first gate insulation layer. The first gate insulation layer and the first conductive layer may be patterned to provide a first gate structure on the substrate 200. The first gate structure may include a first gate insulation layer pattern 204 and a first conductive layer pattern 206 stacked on the substrate 200. The first conductive layer pattern 206 may be provided by depositing polysilicon doped with N-type impurities, for example.

The first conductive layer pattern 206 may extends over the isolation layer 202 to provide a region connected to a plug, which may be provided in a successive process. A gate spacer 208 may be provided on a side face of the first gate structure. A liner 212, which may include nitride, and which may be used as an etch stop layer, may be provided on the gate spacer 208, the first conductive layer pattern 206, and the substrate 200.

N-type impurities may be implanted into the substrate 200 adjacent to the first gate structure to provide first source/drain regions 210 in the substrate 200. Thus, a first N-type transistor, which may include the first gate structure and the first source/drain regions 210, may be provided on the substrate 200 as a pull-down transistor for a fill CMOS SRAM device.

A lower insulation layer 214 may be provided on the substrate 200 to a sufficient thickness to cover the first transistor. The lower insulation layer 214, which may be fabricated from an insulation material such as silicon oxide (for example), may be provided on the substrate 200. The lower insulation layer 214 may be polished by a polishing process such as a CMP process (for example) to planarize a top surface thereof.

The lower insulation layer 214 may be etched away from the substrate 200 to provide a first opening 215 through which the substrate 200 may be exposed.

A first epitaxial layer pattern 216 may be provided in the first opening 215. The first epitaxial layer pattern 216 may fill the first opening 215. The first epitaxial layer pattern 216 may act as a seed for forming a first preliminary single crystalline layer pattern 218.

The first preliminary single crystalline silicon pattern 218 may be provided on the lower insulation layer 214 and the first epitaxial layer pattern 216. The first preliminary single crystalline silicon pattern 218 may act as a first upper active area for forming a pull-up device.

The first epitaxial layer pattern 216 and the first preliminary single crystalline silicon pattern 218 may be provided as described with reference to FIG. 3.

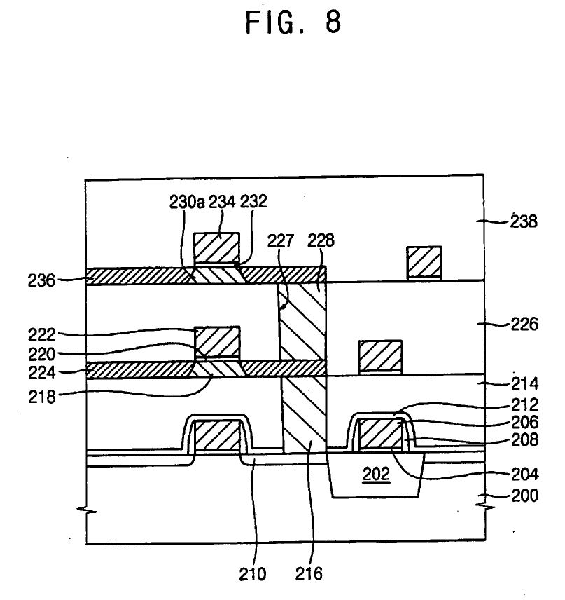

Referring to FIG. 8, a second gate insulation layer (not shown) may be provided on the first preliminary single crystalline silicon pattern and the lower insulation layer 214. A second conductive layer (not shown) may be provided on the second gate insulation layer. The second conductive layer and the second gate insulation layer may be patterned by a photolithography process to provide a second gate structure on the first preliminary single crystalline silicon pattern and the lower insulation layer 214, respectively. The second gate structure may include a second gate insulation layer pattern 220 and a second conductive layer pattern 222 that may be stacked on the first preliminary single crystalline silicon pattern and the lower insulation layer 214. The first preliminary single crystalline silicon pattern 218 may be doped with appropriate impurities, as is well known in this art, to form a first single crystalline silicon pattern that may include channel region 218a and second source/drain regions 224. For example, P-type impurities may be implanted into the first preliminary single crystalline silicon pattern 218 adjacent to the second gate structure, so that the second source/drain regions 224 may be provided adjacent to the channel region 218a of the first single crystalline silicon pattern. The second source/drain regions 224 may extend to a side end portion of the channel region 218a.

The second conductive layer pattern 222 may extend over the lower insulation layer 214 to provide a region connected to a plug, which may be provided in a successive process. Thus, the second P-type transistor including the second gate structure and the second source/drain regions 224 may be provided on the lower insulation layer 214 as a pull-up transistor of the full CMOS SRAM device.

an insulating interlayer 226 may be provided on the first single crystalline silicon pattern and the lower insulation layer 214.

A second opening 227, through which the second source/drain regions may be exposed, may be provided through the insulating interlayer 226.

A second epitaxial layer pattern 228 may be provided in the second opening 227 to fill the second opening 227. The second epitaxial layer pattern 228 may act as a seed for forming a second preliminary single crystalline silicon pattern.

The second epitaxial layer pattern 228 and the second preliminary single crystalline silicon pattern may be provided as described with reference to FIG. 3.

A third gate insulation layer (not shown) may be provided on the second preliminary single crystalline silicon pattern. A third conductive layer (not shown) may be provided on the third gate insulation layer. The third conductive layer and the gate insulation layer may be patterned to form a third gate structure including a third gate insulation layer pattern 232 and a third conductive layer pattern 234 provided on the second preliminary single crystalline silicon pattern. The second preliminary single crystalline silicon pattern may be doped with appropriate impurities, as is well known in this art, to form a second single crystalline silicon pattern that may include channel region 230a and second source/drain regions 236. For example, N-type impurities may be implanted into the second preliminary single crystalline silicon pattern adjacent to the third gate structure, so that third source/drain regions 236 may be provided adjacent to the channel region 230a of the second single crystalline silicon pattern.

Thus N-type third transistors, which may include the third gate structure and the third source/drain regions 236, and which may be provided on the insulating interlayer 226, may be provided as access devices. The third conductive layer pattern 234 is formed even over the insulating interlayer 226.

An upper insulation layer 238 may be provided on the second single crystalline silicon pattern and the insulating interlayer 226.

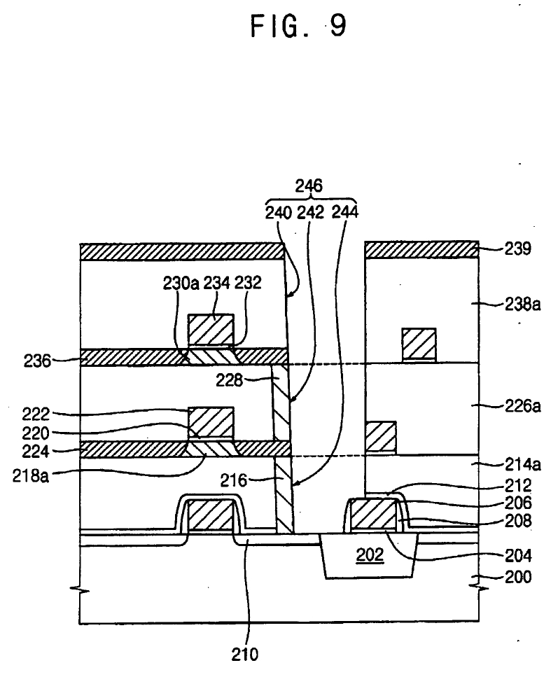

Referring to FIG. 9, a hard mask layer (not shown) and an anti-reflection layer (not shown) may be provided on the upper insulation layer 238 by depositing silicon nitride and/or silicon oxynitride using a CVD process, for example. The anti-reflection layer may be provided by depositing silicon oxynitride using the CVD process, for example.

The anti-reflection layer and the hard mask layer may be patterned by a photolithography process (for example) to provide a hard mask pattern 239 and an anti-reflection pattern (not shown) on the upper insulation layer 238.

The upper insulation layer 238 may be exposed thorough the hard mask pattern 239 and the anti-reflection pattern. The exposed portion of the upper insulation layer 238 may overlap the first and the second epitaxial layer patterns 216 and 228.

The upper insulation layer 238 and the second single crystalline silicon pattern may be removed from the substrate 200 by an etching process (for example) using the hard mask pattern 239 as an etching mask, to form a third opening 240 through which top surfaces of the insulating interlayer 226 and the second epitaxial layer pattern 228 may be exposed. The upper insulation layer 238, after patterning, may be referred to as an upper insulation layer pattern 238a. A sidewall of the second single crystalline silicon pattern (e.g., the third source/drain regions 236) may be exposed in the third opening 240.

Pull-up and pull-down transistors for a full CMOS SRAM device may be electrically connected with each other by the plug in such a way that the pull-up and pull-down transistors may form a flip-flop structure. As a result, the plug may not contact with the third conductive layer pattern 234 used as a gate electrode of the access transistor. For the above reason, the third opening 240 may be provided at a distance spaced apart from the third conductive layer pattern 234. The third conductive layer pattern 234 may not be exposed through the third opening 240.

The second epitaxial layer pattern 228, the first single crystalline silicon pattern under the second epitaxial layer pattern 228 and the insulating interlayer 226 may be etched to form a fourth opening 242 that may communicate with the third opening 240. Top surfaces of the lower insulation layer 214 and the first epitaxial layer pattern 216 may be exposed through the third and the fourth openings 240 and 242. The insulating interlayer 226, after patterning, may be referred to as a lower insulation layer pattern 226a A sidewall of the first single crystalline silicon pattern (e.g., the second source drain regions 224) may be exposed by the fourth opening 242.

The fourth opening 242 may have a sufficient width so that a portion of the second conductive layer pattern 222 (which may be positioned over the lower insulation layer 214) may be exposed by the fourth opening 242. A portion of the second conductive layer pattern 222 (which may be positioned over the channel region 218a of the first single crystalline silicon pattern) may not be exposed by the fourth opening 242.

Portions of the first epitaxial layer pattern 216 and the lower insulation layer 214 that may be exposed by the fourth opening 242 and a portion of the liner 212 (which may exist below the portion of the lower insulation layer 214 exposed by the fourth opening 242) may be etched to form a fifth opening 244 through the lower insulation interlayer 214. A portion of the first conductive layer pattern 206 (which may be provided over the isolation layer 202) may be exposed by the fifth opening 244.

Most of the anti-reflection pattern and the hard mask pattern 239 may be removed from the substrate 200 with the etching processes that may be associated with the formation of the third, the fourth and the fifth openings 240, 242 and 244, respectively.

As shown in FIG. 9, a portion of the first epitaxial layer pattern 216 may remain on the substrate 200 and may be exposed in the fifth opening 244. A portion of the second epitaxial layer pattern 228 may remain on the first single crystalline silicon pattern and may be exposed in the fourth opening 242. The third, the fourth, and the fifth openings 240, 242, and 244 may be referred to as a contact hole 246.

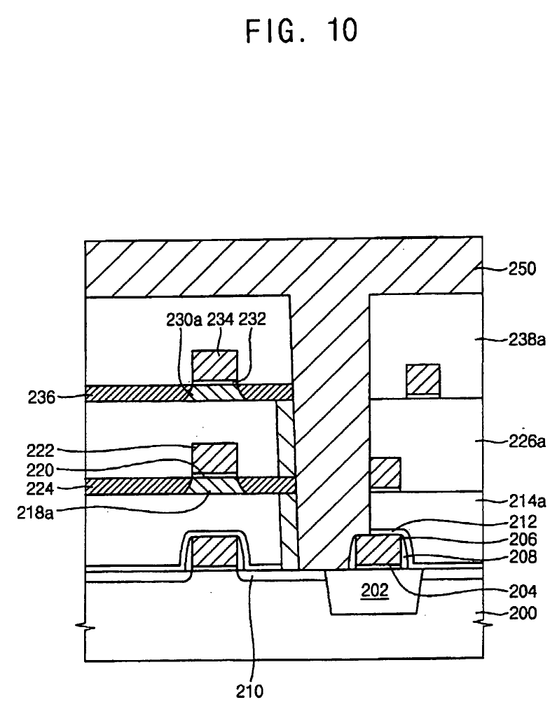

Referring to FIG. 10, a silicon germanium layer 250 may be provided on the upper insulation layer pattern 238a to fill the contact hole 246. The silicon germanium layer 250 may be doped in situ with impurities in Group III and/or Group V of the periodic table.

The silicon germanium may resist diffusing into the lower and the upper insulation layer patterns 214a and 238a and the insulating interlayer pattern 226a, so that a diffusion barrier layer may not be provided on an inner surface of the contact hole 246. In addition, the silicon germanium layer 250 may have substantially the same crystal structure as the first and the second single crystalline silicon patterns. Accordingly, when the substrate 200 comprises single crystalline silicon, a crystal structure of the silicon germanium layer 250 may be substantially the same as that of the substrate 200 and the first and the second single crystalline silicon patterns, so that an ohmic layer may not be provided on contact regions between the silicon germanium layer 250 and the single crystalline silicon substrate 200 and/or the first and the second single crystalline silicon patterns. The first and the second single crystalline silicon patterns may be sufficiently prevented from being separated from the substrate 200.

The silicon germanium layer 250 may be deposited and/or grown. Impurities of the silicon germanium layer 250 may be activated at a temperature of about 400 to about 550° C., for example.

The silicon germanium layer 250 may be provided by a low pressure CVD (LPCVD) process and/or an epitaxial growth process, for example. However, the epitaxial growth process may consume a significant amount of time.

An LPCVD process for the formation of the silicon germanium layer 250 may proceed as follows.

When the LPCVD process for providing the silicon germanium layer 250 is performed at a temperature under about 400° C., the yield rate of the silicon germanium layer 250 may tend to be negligible, thereby reducing productivity. When the LPCVD process for providing the silicon germanium layer 250 is performed at a temperature over about 550° C., neighboring patterns and/or unit elements may be degraded. Thus, the silicon germanium layer 250 may be deposited at a temperature of about 400° C. to about 550° C. In an example embodiment of the present invention, the silicon germanium layer 250 may be deposited at a temperature of about 450° C. to about 500° C.

Additionally, the silicon germanium layer 250 may be deposited under a chamber pressure of about 0.1 to about 1.0 Torr. In an example embodiment of the present invention, the silicon germanium layer 250 may be deposited under a chamber pressure of about 0.3 to about 0.5 Torr.

In the above LPCVD process, silane (SiH₄) gas (for example) may be used as a silicon source gas and germane (GeH₄) gas (for example) may be used as a germanium source gas. A flow rate ratio of the germanium source gas with respect to the silicon source gas may be ranged from about 0.7 to about 1.3.

In an example embodiment of the present invention, a doping gas may be provided into a process chamber of an LPCVD system together with the silicon source gas and the germanium source gas, so that elements in the doping gas may be doped in situ into the silicon germanium layer 250 as impurities. For example, the doping gas for doping the silicon germanium layer 250 with elements in Group V of the periodic table may include phosphine (PH₃) gas and arsine (AsH₃) gas, and the doping gas for doping the silicon germanium layer 114 with elements in Group III of the periodic table may include diborane (B₂H₆) gas.

As described above, the crystalline silicon germanium layer 250 may be obtained at a temperature of about 400° C. to about 550° C. Additionally, because the impurities doped into the silicon germanium layer 250 may be sufficiently activated, an additional heat treatment to the crystalline silicon germanium layer 250 to activate the impurities may be avoided.

Turning back to FIG. 6, the silicon germanium layer 250 may be polished via a chemical mechanical polishing (CMP) process and/or an etch-back process (for example) until a top surface of the upper insulation layer pattern 238a may be exposed. Here, the silicon germanium layer 250 may remain in the contact hole 246 to form the plug 250a in the contact hole 246.

According to example, non-limiting embodiments of the present invention, crystalline silicon germanium may allow a plug in a semiconductor device to be processed at such a sufficiently low temperature that unit elements of the semiconductor device are not deteriorated by heat. In addition, when the plug is provided using crystalline silicon germanium, a barrier layer and/or an ohmic layer may not be provided so that a single crystalline silicon pattern may not be inadvertently removed. Thus, a yield and a reliability of a stacked semiconductor device may increase.

The foregoing is illustrative of example embodiments of the present invention and is not to be construed as limiting thereof. Although example embodiments of the invention have been described, those skilled in the art will readily appreciate that many and varied modifications may be suitably implemented without materially departing from the novel teachings and advantages of this invention. Accordingly, all such modifications are intended to fall within the spirit and scope of this invention as defined in the following claims.

What is claimed is:

1. A semiconductor device comprising:
a substrate;
a layered structure provided on the substrate, the layered structure having a contact hole, the layered structure including
a lower insulation layer pattern provided on the substrate,
a single crystalline silicon pattern provided on the lower insulation layer pattern, and
an upper insulation layer pattern provided on the single crystalline silicon pattern,
the single crystalline silicon pattern and the substrate being exposed through the contact hole; and
a plug including crystalline silicon germanium positioned in the contact hole, the plug being electrically connected to the single crystalline silicon pattern and the substrate.

2. The semiconductor device of claim 1, wherein the plug includes impurities in at least one of Group III and Group V of the periodic table.

3. The semiconductor device of claim 1, wherein the silicon germanium included in the plug is fabricated at a temperature of about 400 to about 550° C. by a chemical vapor deposition (CVD) process.

4. The semiconductor device of claim 1, wherein silicon germanium included in the plug is fabricated by an epitaxial growth process.

5. The semiconductor device of claim 1, wherein transistors are provided on the substrate and the single crystalline silicon pattern.

6. The semiconductor device of claim 5, wherein source/drain regions of the transistors extend to an end portion of the single crystalline silicon pattern making contact with the plug.

7. The semiconductor device of claim 5, wherein the plug is connected to at least one gate electrode of the transistors.

8. The semiconductor device of claim 1, further comprising an epitaxial layer pattern provided in the lower insulation layer pattern, the epitaxial layer pattern being used as a seed for forming the single crystalline silicon pattern.

9. A method of manufacturing a semiconductor device, comprising:
providing a layered structure on a substrate, the layered structure including a lower insulation layer pattern provided on the substrate, a single crystalline silicon pattern provided on the lower insulation layer pattern, and an upper insulation layer pattern provided on the single crystalline silicon pattern;
providing a contact hole through the layered structure by etching the upper insulation layer pattern, the single crystalline silicon pattern, and the lower insulation layer pattern to expose the single crystalline silicon pattern and the substrate;
providing a crystalline silicon germanium layer on the layered structure to fill the contact hole; and
providing a plug in the contact hole by planarizing the silicon germanium layer until a top surface of the layered structure is exposed, the plug being electrically connected to the single crystalline silicon pattern and the substrate.

10. The method of claim 9, wherein the silicon germanium layer is formed at a temperature of about 400 to about 500° C. by a CVD process.

11. The method of claim 10, wherein the silicon germanium layer is formed under a pressure of about 0.1 to about 1.0 Torr.

12. The method of claim 10, wherein silane (SiH₄) gas is used as a silicon source gas, and germane (GeH₄) gas is used as a germanium source gas in the CVD process.

13. The method of claim 9, wherein the silicon germanium layer is formed by an epitaxial growth process.

14. The method of claim 9, further comprising forming the silicon germanium layer and doping with impurities, wherein the impurities include elements in at least one of Group III and Group V of the periodic table.

15. The method of claim 9, further comprising forming a transistor on each of the substrate and the single crystalline silicon pattern.

16. The method of claim 15, wherein the contact hole exposes at least one gate electrode of the transistors.

17. The method of claim 9, further comprising forming an epitaxial layer pattern in the lower insulation layer pattern, the epitaxial layer pattern being used as a seed for forming the single crystalline silicon pattern.

18. A semiconductor device comprising:
a first transistor of a first conductive type provided on a substrate, the first transistor including a first impurity region and a first gate electrode;
a lower insulation layer pattern provided on the substrate, the lower insulation layer pattern having a first opening through which the first impurity region and the first gate electrode are exposed;
a first single crystalline silicon pattern provided on the lower insulation layer pattern;
a second transistor of a second conductive type provided on the first single crystalline silicon pattern, the second transistor including a second impurity region and a second gate electrode;
an insulating interlayer pattern provided on the lower insulation layer pattern, the insulating interlayer pattern having a second opening through which the second impurity region and the second gate electrode are exposed, the second opening being connected to the first opening;
a second single crystalline silicon pattern provided on the insulating interlayer pattern;
a third transistor of the first conductive type provided on the second single crystalline silicon pattern, the third transistor including a third impurity region and a third gate electrode;
an upper insulation layer pattern provided on the insulating interlayer pattern, the upper insulation layer pattern having a third opening through which the third impurity region is exposed, the third opening being connected to the second opening; and
a plug filling the first, the second and the third openings, the plug including crystalline silicon germanium.

19. The semiconductor device of claim 18, wherein the plug is doped with impurities, and wherein the impurities include elements in at least one of Group III and Group V of the periodic table.

20. The semiconductor device of claim 18, wherein the plug is formed at a temperature of about 400 to about 500° C. by a CVD process.

21. A method of manufacturing a semiconductor device comprising:
providing a first transistor of a first conductive type on a substrate, the first transistor including a first impurity region and a first gate electrode;
providing a lower insulation layer pattern on the substrate to cover the first transistor;
providing a first single crystalline silicon pattern on the lower insulation layer pattern;
providing a second transistor of a second conductive type on the first single crystalline silicon pattern, the second transistor including a second impurity region and a second gate electrode;
providing an insulating interlayer pattern on the first single crystalline silicon layer to cover the second transistor;
providing a second single crystalline silicon pattern on the insulating interlayer pattern;
providing a third transistor of the first conductive type on the second single crystalline silicon pattern, the third transistor including a third impurity region and a third gate electrode;
providing an upper insulation layer pattern on the insulating interlayer pattern to cover the third transistor,
providing a contact hole by etching the upper insulation layer pattern, the insulating interlayer pattern, and the lower insulation layer pattern to expose the first, the second and the third impurity regions and the first and the second gate electrodes;
providing a crystalline silicon germanium layer on the upper insulation layer pattern to fill the contact hole; and
providing a plug in the contact hole by planarizing the silicon germanium layer until a top surface of the upper insulation layer pattern is exposed.

22. The method of claim 21, further comprising doping with impurities, the impurities include elements in at least one of Group III and Group V of the periodic table.

23. The method of claim 21, the silicon germanium layer is formed at a temperature of about 400 to about 550° C. by a CVD process.

24. A semiconductor device comprising:
a substrate;
a lower insulation layer pattern provided on the substrate;
a single crystalline silicon pattern provided on the lower insulation layer pattern;
an upper insulation layer pattern provided on the single crystalline silicon pattern; and
a plug including crystalline silicon germanium extended through the lower insulation layer pattern, the single crystalline silicon pattern and the upper insulation layer pattern, the plug being electrically connected to the single crystalline silicon pattern and the substrate.
